(19) United States
(12) Patent Application Publication
(10) Pub. No.: US 2012/0119208 A1
(43) Pub. Date: May 17, 2012

(54) SEMICONDUCTOR APPARATUS AND FABRICATING METHOD THEREOF

(75) Inventor: Sang Hoon SHIN, Icheon-si (KR)

(73) Assignee: HYNIX SEMICONDUCTOR INC., Icheon-si (KR)

(21) Appl. No.: 13/181,802

(22) Filed: Jul. 13, 2011

(30) Foreign Application Priority Data
Nov. 16, 2010 (KR) 10-2010-0113769

(51) Int. Cl. H01L 23/544; H01L 23/48; H01L 21/28

(52) U.S. Cl. 257/48; 438/460; 257/774; 257/E23.179; 257/E21.158; 257/E23.011

(57) ABSTRACT

A semiconductor apparatus includes a semiconductor chip formed on a predetermined area of a wafer, wafer test block formed on an area outside the predetermined area, and signal line for electrically connecting the semiconductor chip to the wafer test block. Through-silicon via is formed to vertically penetrate the signal line.

### CROSS-REFERENCES TO RELATED APPLICATION

The present application claims priority under 35 U.S.C. §119(a) to Korean application number 10-2010-0113769, filed on Nov. 16, 2010, in the Korean Intellectual Property Office, which is incorporated herein by reference in its entirety.

### BACKGROUND

1. Technical Field

The present invention relates to a semiconductor apparatus and a fabricating method thereof.

2. Related Art

As shown in FIG. 1, a conventional semiconductor apparatus 1 includes a plurality of semiconductor chips formed on a wafer.

Each chip includes several blocks such as a normal operation block (NOB), package test blocks (PTBs), package test pads (PPs), wafer test blocks (WTBs), and wafer test pads (WPs).

The wafer test block (WTB) is electrically connected to the wafer test pads (WPs). More specifically, the wafer test block (WTB) and the wafer test pads (WPs) are electrically connected to a circuit configuration of the normal operation block (NOB) inside the chip.

Each chip area on a wafer area is defined by the scribe lines, and sawing areas are defined on the wafer area outside the scribe lines of each chip and between the chips on the wafer.

After performing a wafer test, the wafer is physically divided to produce individual chips, where each chip has a predetermined margin outside the scribe lines in the sawing areas. A package may then be formed by utilizing the individual chips.

After performing a wafer test, the wafer test blocks (WTBs) and the wafer test pads (WPs) in each chip are not used any more.

This does not help to reduce the chip size when the wafer test blocks (WTBs) and the wafer test pads (WPs), which are no longer used after the wafer test, remain in the chip.

### SUMMARY

A semiconductor apparatus capable of substantially preventing an increase in a chip size due to a wafer test-related configuration and a fabricating method thereof are described herein.

In one embodiment of the present invention, a semiconductor apparatus including a wafer includes: semiconductor chip formed on a predetermined area of the wafer; wafer test block formed on an area outside the predetermined area; and signal line for electrically connecting the semiconductor chip to the wafer test block, wherein through-silicon via is formed to vertically penetrate the signal line.

In another embodiment of the present invention, a method for fabricating a semiconductor apparatus including a semiconductor chip includes the steps of: forming semiconductor chip on a wafer; forming wafer test block on an area outside an area where the semiconductor chip is formed; forming signal line for electrically connecting the wafer test block to the semiconductor chip; and forming through-silicon via on the signal line after a wafer test is completed.

In another embodiment of the present invention, a semiconductor apparatus includes: a circuit block configured to perform a predetermined operation; a first signal line having a first end coupled to the circuit block; a through-silicon via having a first side coupled to a second end of the first signal line, the first end facing the second end; and a second signal line extending from a second side of the through-silicon via to a cutting surface of the semiconductor apparatus, the first side facing the second side.

### BRIEF DESCRIPTION OF THE DRAWINGS

Features, aspects, and embodiments are described in conjunction with the attached drawings, in which:

FIG. 1 is a diagram illustrating a layout of a wafer according to the conventional art;

FIG. 2 is a diagram illustrating a layout of a wafer according to an embodiment of the invention;

FIG. 3 is a diagram illustrating a layout of a wafer including through-silicon vias according to an embodiment of the invention; and

FIGS. 4a to 4c are diagrams illustrating layouts of chips taken along line A-A′ of FIG. 3.

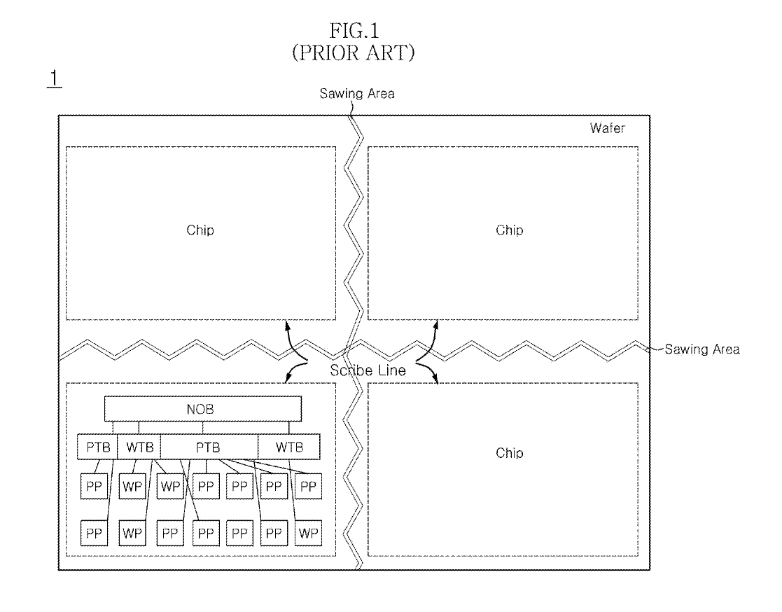

### DETAILED DESCRIPTION

Hereinafter, a semiconductor apparatus and a fabricating method thereof according to the present invention will be described in detail with reference to the accompanying drawings through exemplary embodiments.

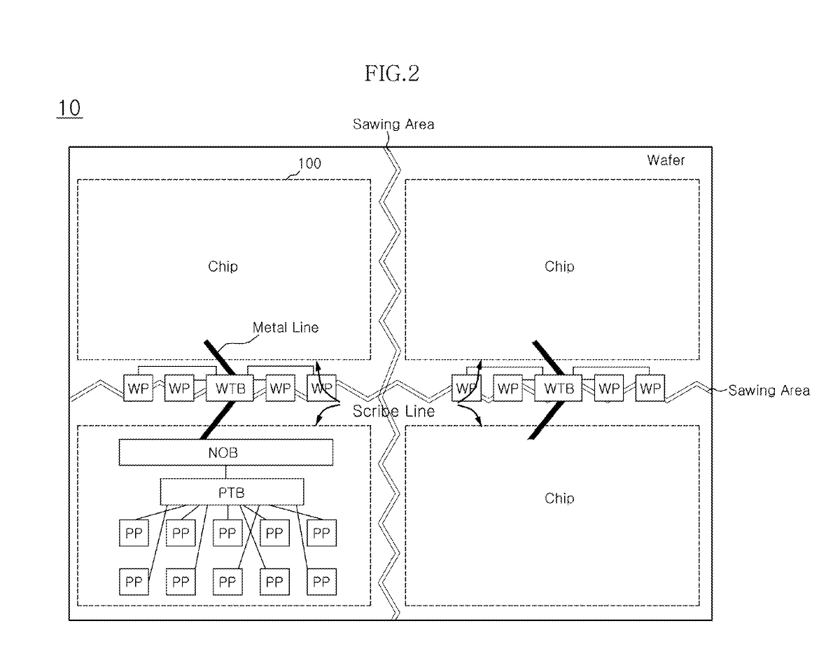

As shown in FIG. 2, a wafer 10 according to an embodiment of the present invention includes a plurality of chips 100, wafer test blocks (WTBs), and wafer test pads (WPs).

An area of each chip 100 with respect to the entire wafer area is defined by the scribe lines, and sawing area are defined on the wafer area outside the scribe lines of each chip and between the chips on the wafer.

Each chip 100 includes a normal operation block (NOB), a package test block (PTB), and package test pads (PPs).

The wafer test blocks (WTBs) and the wafer test pads (WPs) are formed in the sawing area outside the scribe lines.

The wafer test blocks (WTBs) and the wafer test pads (WPs) are electrically connected to the chips 100 through signal lines such as metal lines.

In detail, the wafer test blocks (WTBs) and the wafer test pads (WPs) according to an embodiment of the present invention are electrically connected to two different chips 100 with the metal lines, so that the wafer test blocks (WTBs) and the wafer test pads (WPs) can be shared by the two different chips 100.

Since the wafer test blocks (WTBs) and the wafer test pads (WPs) are formed in the sawing area, which is outside the chip area, they do not take any part in the chip size. Unlike the conventional design, the wafer test blocks (WTBs) and the wafer test pads (WPs) according to an embodiment of the present invention do not contribute to the increased chip size.

After performing a wafer test utilizing the wafer test blocks (WTBs) and the wafer test pads (WPs), a three-dimensional stack package comprising two or more chips 100 can be formed

The stacked two or more chips 100 in a three-dimensional stack package connected to each other via through-silicon vias (TSVs) for signal transmission and communication between the two or more stacked chips 100 in the three-dimensional stack package.

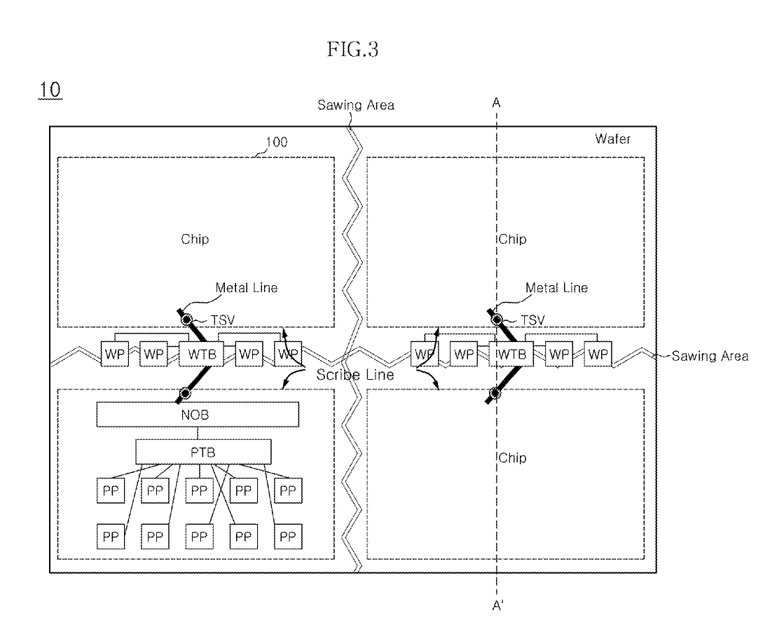

According to an embodiment of the present invention as shown in FIG. 3, forming TSVs is a necessary step for forming a three-dimensional stack package as such a TSV is formed on the respective metal line in each chip area.

Each metal line is separated into two by formation of a TSV on the metal line, and the two separated metal lines are then isolated from each other by an insulation layer of the TSV.

The TSV, which was formed on the metal line in each chip area, may be one of the TSVs for supplying power or one of the TSVs formed for various signal communications. Dummy TSVs can also be formed for purposes other than signal communication or power supply.

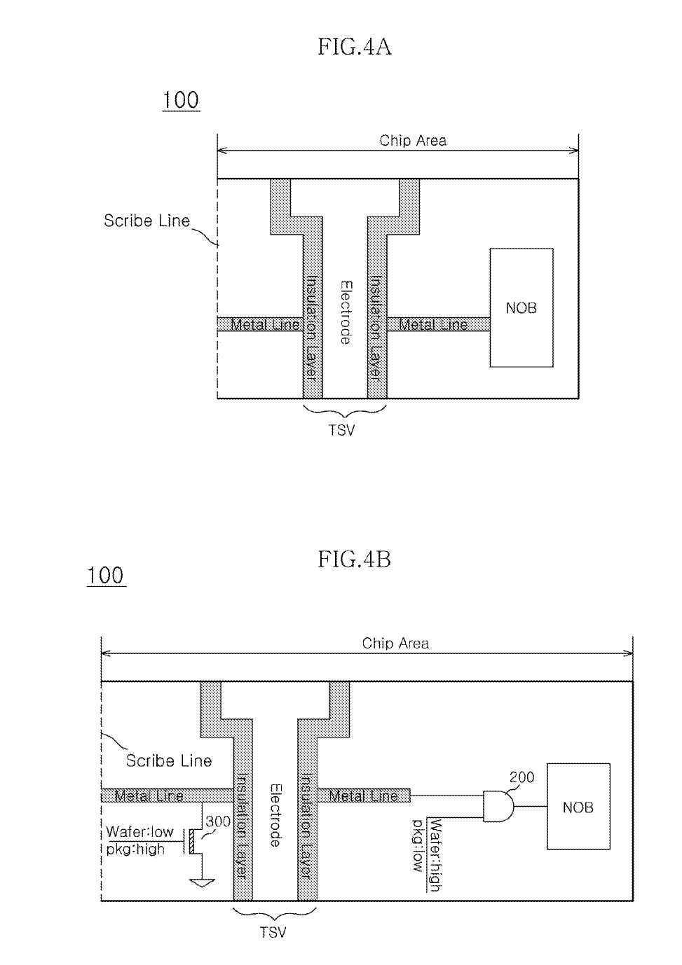

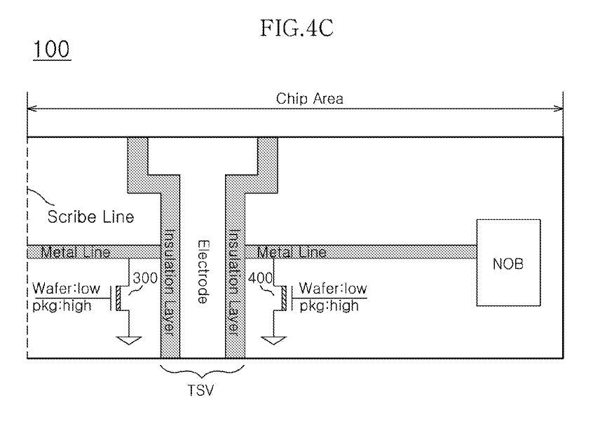

Referring to FIG. 4A, a TSV includes an insulation layer surrounding the electrode.

The two separated metal lines on both sides of the TSV are electrically isolated by the insulation layer of the TSV, and this electrically isolates the normal operation block (NOB) from the external environment, and this also means that the chip 100 can be electrically isolated from the external environment.

As described above with respect to FIG. 3, after forming the TSVs, each chip 100 is physically divided (that is, cut) with a predetermined margin in the sawing area outside the scribe lines, so that the three-dimensional stack package can be formed using two or more of the divided chips.

According to an embodiment of the present invention, even after the chip 100 is physically isolated by the TSV formed on the metal line due to the insulation layer of the TSV, the chip 100 is electrically isolated from the external environment.

That is, the cut surface of the metal line inside the TSV hole area of the physically divided chip 100 could be externally exposed. However, the exposed metal line surface is covered by the insulation layer of the TSV so that the internal environment of the chip 100 would not be affected by the external environment through the metal line separated by the TSV.

Referring to FIG. 4A, even though the chip 100 can be electrically isolated from the external environment by the insulation layer in the through silicon via (TSV), the metal lines on both sides of the TSV can end up in a floating state.

Thus, before the metal lines connected to the chips on a wafer are separated and electrically isolated by forming the through silicon vias (TSVs) on the metal lines (also to be referred as “a wafer state”), the signals are communicated through the metal lines in the wafer, and, when the chips on the wafer are physically divided into individual chips, each metal lines is held to a predetermined voltage level (e.g., a ground level), so as to provide more stabilized operation of the chip 100. Examples of a circuit configuration for this according to an embodiment of the present invention are described with reference to FIGS. 4B and 4C below.

In FIG. 4B, a transistor 300 and an AND gate 200 are coupled to the metal lines, respectively, as the elements for allowing signal communication through the metal lines in a wafer state and for locking the metal lines to a predetermined level (e.g., a low level) after physically dividing the chips 100 in the wafer.

A source terminal of the transistor 300 in FIG. 4B is grounded, and a drain terminal thereof is coupled to the metal line that is not connected to the normal operation block (NOB).

In a wafer state (i.e., before isolating the metal lines by forming TSVs), a low level signal is applied to a gate terminal of the transistor 300, so that the signal from the wafer test block (WTB) are transferred to the normal operation block (NOB) through the metal line. In a package state, a high level signal is applied to the gate terminal of the transistor 300 to lock the metal line to a ground level, so that the TSV is shielded from the external electrical environment.

On the other side of the TSV (on the side of NOB as shown in FIG. 4B), the metal line is coupled to one end of the AND gate 200 as an electrical shielding element, and the output terminal of the AND gate 200 is coupled to the normal operation block (NOB).

In a wafer state, a high level signal is applied to the other end of the AND gate 200, so that the signal of the wafer test block (WTB) can be received In the package state, a low level signal is applied to the other end of the AND gate 200 to lock a signal input to the normal operation block (NOB) to a ground level, so that the TSV is electrically shielded from the normal operation block (NOB).

FIG. 4C is substantially identical to FIG. 4B, except that a transistor 400 instead of the AND gate 200 is coupled to the respective metal line.

In a wafer state, a low level signal is applied to the transistor 400, so that the signals of the wafer test block (WTB) can be received. In the package state, a high level signal is applied to the transistor 400 to lock a signal input to the normal operation block (NOB) to a ground level, so that the TSV is electrically shielded from the normal operation block (NOB).

According to an embodiment of the present invention, the wafer test-related configuration is arranged in the sawing areas outside scribe lines of a wafer and is electrically isolated from the chips after performing a wafer test, so that the wafer layout margin can be increased while reducing or substantially maintaining each chip size on a wafer.

While certain embodiments have been described above, it will be understood to those skilled in the art that the embodiments described are by way of example only. Accordingly, the semiconductor apparatus and the fabricating method thereof described herein should not be limited based on the described embodiments. Rather, the semiconductor apparatus and the fabricating method thereof described herein should only be limited in light of the claims that follow when taken in conjunction with the above description and accompanying drawings.

What is claimed is:

1. A semiconductor wafer comprising:
a semiconductor chip formed in a predetermined area of the wafer;
a wafer test block formed outside the predetermined area of the wafer; and
a signal line electrically connecting the semiconductor chip and the wafer test block on the wafer,
wherein a through-silicon via is formed to vertically penetrate the signal line.

2. The semiconductor wafer according to claim 1, wherein the semiconductor chip comprises:
a normal operation block,
wherein the normal operation block is coupled to the wafer test block through the signal line.

3. The semiconductor wafer according to claim 1, wherein the through-silicon via is formed in the predetermined area of the wafer.

4. The semiconductor wafer according to claim 1, further comprising:
a switching element electrically connected to the signal line to allow the signal line to have a specific voltage level.

5. The semiconductor wafer according to claim 1, further comprising:
first and second switching elements electrically connected to signal lines at both sides of the through-silicon via to allow the signal lines to have a specific voltage level.

6. A method for fabricating semiconductor chips, comprising the steps of:
forming semiconductor chips on a wafer, wherein a sawing area separate two chips formed on the wafer;
forming a wafer test block in the sawing area or an area outside the area where the semiconductor chip is formed;
forming a signal line for electrically connecting the wafer test block and one of the semiconductor chips; and
forming a through-silicon via on the signal line after completing a wafer test, wherein the signal line is separated into two separated signal lines on both sides of the through-silicon via.

7. The method according to claim 6, further comprising a step of:
separating the semiconductor chips on the wafer into individual chips after forming the through-silicon via.

8. The method according to claim 6, wherein, in the step of forming the through-silicon via, the through-silicon via is formed on the signal line outside the sawing area.

9. The method according to claim 6, further comprising a step of:
forming a switching element electrically connected to each one of the separated signal lines on both sides of the through-silicon via.

10. A semiconductor apparatus comprising:
a circuit block configured to perform a predetermined operation;
a first signal line having a first end coupled to the circuit block;
a through-silicon via having a first side coupled to a second end of the first signal line; and
a second signal line extending from a second side of the through-silicon via to a cutting surface of the semiconductor apparatus.

11. The semiconductor apparatus according to claim 10, further comprising:
a switching element electrically connected to the first signal line or the second signal line to allow the first signal line or the second signal line to have a specific voltage level.

12. The semiconductor apparatus according to claim 10, further comprising:
a first switching element electrically connected to the first signal line to allow the first signal line to have a specific voltage level; and
a second switching element electrically connected to the second signal line to allow the second signal line to have a specific voltage level.

13. The semiconductor apparatus according to claim 12, wherein the semiconductor apparatus comprises a semiconductor chip suitable for packaging.
